(19) United States
(12) Patent Application Publication
(10) Pub. No.: US 2017/0279401 A1
(43) Pub. Date: Sep. 28, 2017

(54) ULTRA WIDE SPECTRUM PHOTOVOLTAIC-THERMOELECTRIC SOLAR CELL

(71) Applicants: STC.UNM, ALBUQUERQUE, NM (US); ARROWHEAD CENTER, INC, LAS CRUCES, NM (US); UNIVERSITY OF GEORGIA, ATHENS, GA (US); INDIANA UNIVERSITY RESEARCH & TECHNOLOGY, BLOOMINGTON, IN (US)

(72) Inventors: Tito Busani, ALBUQUERQUE, NM (US); Olga Lavrova, ALBUQUERQUE, NM (US); Julio Martinez, LAS CRUCES, NM (US); John Shelnutt, ALBUQUERQUE, NM (US); Shixiong Zhang, BLOOMINGTON, IN (US)

(73) Assignees: STC.UNM, ALBUQUERQUE, NM (US); ARROWHEAD CENTER, INC, LAS CRUCES, NM (US); UNIVERSITY OF GEORGIA, ATHENS, GA (US); INDIANA UNIVERSITY RESEARCH & TECHNOLOGY, BLOOMINGTON, IN (US)

(21) Appl. No.: 15/504,840

(22) PCT Filed: Aug. 18, 2015
(86) PCT No.: PCT/US15/45762

§ 371 Date: Feb. 17, 2017

Related U.S. Application Data
(60) Provisional application No. 62/038,704, filed on Aug. 18, 2014.

(51) Int. Cl. H02S 10/30; H01G 9/20; H01G 9/00; H02S 40/38

(52) U.S. Cl. CPC H02S 10/30; H02S 40/38; H01G 9/2022; H01G 9/204; H01G 9/2013; H01G 9/2059; H01G 9/0029; H01L 51/006

(57) ABSTRACT

The present invention is a photovoltaic-thermoelectric solar cell and a method of manufacturing a photovoltaic-thermoelectric solar cell. The solar cell includes a substantially transparent electrode, an organometallic photovoltaic material disposed on the transparent electrode, and a cathode disposed on the organometallic photovoltaic material. The organometallic photovoltaic material may be a porphyrin nanomaterial.

### CROSS-REFERENCE TO RELATED APPLICATIONS

This application claims the priority benefit of U.S. provisional application No. 62/038,704, entitled “Ultra Wide Spectrum Photovoltaic-Thermoelectric Solar Cell,” filed on Aug. 18, 2014, the disclosure of which is incorporated herein by reference.

### STATEMENT REGARDING FEDERALLY SPONSORED RESEARCH OR DEVELOPMENT

This invention was made with government support under contract number GR000096 awarded by the National Aeronautics and Space Administration (NASA). The government has certain rights in the invention.

### BACKGROUND OF THE INVENTION

Field of the Invention (Technical Field)

The present invention is directed toward a photovoltaic-thermoelectric solar cell, and more particularly to the integration of organometallic and inorganic nanostructured materials in a photovoltaic (PV)-thermoelectric (TE) component solar cell.

Background

Solar cells are utilized to convert light energy to useable electrical voltages and currents through the photovoltaic effect. Briefly, a typical solar cell includes an interface between n-type and p-type transparent semiconductor materials. Light shining on the materials adjacent to the interface creates hole-electron pairs in addition to those otherwise present, and the minority charge carriers migrate across the interface in opposite directions. There is no compensation of flow of majority carriers, so that a net electrical charge results. A useful electrical current is then obtained in an external electrical circuit by forming ohmic contacts to the materials on either side of the interface.

In general terms, a photovoltaic solar cell is fabricated by depositing or attaching the appropriate semiconductor layers onto a substrate, and then adding additional components to complete the cell. Individual solar cells are connected together into large arrays to deliver power of the desired voltage and current. The ratio of power output to area of the solar cell array is an important design parameter, since the required power output could in principle be satisfied, for example, by larger numbers of low power density solar cells made of silicon or by smaller numbers of high power density solar cells made of gallium arsenide. Large numbers of solar cells require more supporting structure and area with solar access (such as the scarce area on rooftops) adding cost and complexity to PV system, and reducing the amount of energy which can be generated on a given site, such as a building or plot of land.

A significant amount of development of PV/TE modules is known. One provides a combination photovoltaic array and solar thermal water heater. A first problem with this configuration is the requirement for a nearby thermal heat requirement, such as heating water. By far, most PV installations are not associated with a heat requirement. Consider the many arrays mounted on office buildings, warehouses, or simply ground mounted. However, even if such a heat load is present, when the water heater component has stored all the hot water possible, such as during a day when there is no use, the water temperature is so high as to render its cooling effect on the photovoltaic module useless. In fact, the module can remain at high temperature when it would otherwise cool down with the evening ambient decline. Another problem with conventional photovoltaic/thermal is its focus on water heating, which can lead to significant temperature gradients across the array, with corresponding thermal stresses. Photovoltaic solar cells having a component for reducing heat to increase the output power have been limited to rejection of the photovoltaic heat to domestic or process water heating. Further problems with this type of cooling include the fact that the cooling effect is often negligible, allowing unacceptable thermal cycling stress on all components and that the thermal load requirements do not allow for optimum design of the electric generation system due to the variability of operating conditions.

Nanostructures self-assembled from organic molecules are of great interest in the PV/TE field. Particular nanostructures also offer opportunities for mimicking the processes that occur in biological photosynthesis to produce fuels, and this is especially true when the organic molecular subunits of the nanostructures are porphyrins. Herein, the PV material may be a self-assembled cooperative binary ionic-type nanomaterial. The nanostructures as the PV portion have improved efficiency over other PV materials.

Thus, there is a continuing need for a hybrid solar cell that integrates photovoltaic and thermoelectric cell elements to increase the ratio of power output to area for solar cells and solar cell arrays and that operates in an ultra-wide spectrum and conversion of a wider solar spectrum energy, thereby increasing the efficiency of solar to electric power conversion. The present invention fulfills this need, and further provides related advantages.

### SUMMARY OF THE INVENTION

### Disclosure of the Invention

An embodiment of the present invention is a photovoltaic-thermoelectric solar cell having a substantially transparent electrode, an organometallic photovoltaic material disposed on the transparent electrode, and a cathode disposed on the organometallic photovoltaic material. The transparent electrode can be an n-type material with a crystalline structure, such as a zinc oxide nanowire photoelectrode or a zinc oxide file photoelectrode. The organometallic photovoltaic material can a porphyrin nanomaterial, such as a self-assembled cooperative binary ionic nanomaterial. The cathode can be a p type thermoelectric nanostructured material, such as a p-type Bi2Te3, p-type Bi0.5Sb1.5Te3, or p-type Bi2Se3 nanostructured materials. The solar cell can include an energy storage component disposed on the cathode. The energy storage component can be an ion battery or a monolithically integrated ion battery. The cathode and the electrode can be in the form of bulk, nanostructure or thin films. The energy storage component can also be integrated with the cathode.

Another embodiment of the present invention is a method of manufacturing a photovoltaic-thermoelectric solar cell. The method includes applying a layer of organometallic photovoltaic material to an electrode, applying a layer of organometallic photovoltaic material to a cathode, and disposing one layer of the applied organometallic photovoltaic material to the other layer of applied organometallic photovoltaic material to form the photovoltaic-thermoelectric solar cell. The method can optionally include applying another layer of organometallic photovoltaic material between the electrode and the cathode to increase an open circuit voltage of the solar cell. The photovoltaic-thermoelectric solar cell has one or more layers of organometallic photovoltaic material disposed between the electrode and the cathode. This method can be performed at room temperature. The organometallic photovoltaic material can be a porphyrin nanomaterial. The electrode can be an n-type material with a crystalline structure and be substantially transparent. The cathode can be a p-type thermoelectric nanostructured material. The method can also optionally include disposing an energy storage component on the cathode. The energy storage component can be a lithium ion silicon nanowire battery.

### BRIEF DESCRIPTION OF THE DRAWINGS

FIG. 1A shows a schematic representation of a photovoltaic-thermoelectric (PV-TE) power generation cell of the present invention.

FIG. 1B is a schematic representation of an embodiment of a photovoltaic thermoelectric energy storage device of the present invention.

FIGS. 2A and 2B show two versions of electron and hole transport schematics across the different materials of the PV-TE solar cell of FIGS. 1A and 1B.

FIG. 3 is an energy diagram with relative energy levels with respect to vacuum for ZnO, CBI, CBI*, and Bi2Te3.

FIG. 4 is a transmission electron microscope (TEM) image of ZnTPPS⁴⁻ adsorbed onto (i.e. porphyrin coating of) a thermoelectric nanowire comprising Bi2Te3.

FIG. 5A is a scanning electron microscope (SEM) image of the thermoelectric characterization platform on which is a p-type Bi2Te3 nanowire coated with twelve SnTNEtOHPyP⁴⁺/ZnTPPS⁴⁻ bilayers. SnTN-EtOH-4-PyP⁴⁺ was the first deposited layer.

FIG. 5B and FIG. 5C are graphs showing results of photoconductivity studies of the CBI/Bi2Te3 nanowire of FIG. 5A at two different temperatures before and after light exposure.

FIG. 6 is a TEM image of a single ZnO NW growth in solution at 75° C.

FIG. 7 is a scanning transmission electron microscopy (STEM) image of five bilayers of alternating ZnTNEtOHPyP and ZnTPPS (i.e. porphyrin coating) on ZnO nanowires.

FIG. 8 is a graph illustrating electrical characterization of ZnO-porphyrin coated nanowires under dark and light-on conditions.

FIG. 9 is a graph illustrating voltage versus current and shows a Voltage Open Circuit (VOC) for an example PV-TE solar cell.

### DETAILED DESCRIPTION OF EMBODIMENTS OF THE INVENTION

A new innovation in solar power generation is the development of photovoltaic (PV) and thermoelectric (TE) hybrid solar systems. This inexpensive solar power system is uniquely designed to increase the power conversion efficiency (PCE) by capturing the entire solar spectrum and substantially reducing the solar energy cost of generation. The PV/TE combination is able to capture ultra-violet (UV), visible and infrared (IR) regions of light. This is advantageous over traditional PV systems that only harvest sunlight through photovoltaic pathways and lose additional energy as heat. The TE component is able to capture heat in the IR region which improve the efficiency dramatically. The hybrid solar cell is preferably produced cheaply and efficiently by using a simple solution method and the integration of naturally abundant materials. A solution manufacturing method decreases the overall cost of the system substantially, improves scalability and the material themselves improve efficiency. The hybrid solar cell preferably utilizes optimal combinations of materials to capture the entire solar spectrum doubling the PCE over traditional panels.

Such solar cells can also be integrated with a lithium-ion battery (power storage cell). A feature of the hybrid solar cell is the pairing of a photovoltaic (PV) component with a thermoelectric (TE) component which results in the conversion of a wider solar spectrum energy. Thus, the efficiency of solar to electric power conversion is increased and can be stored.

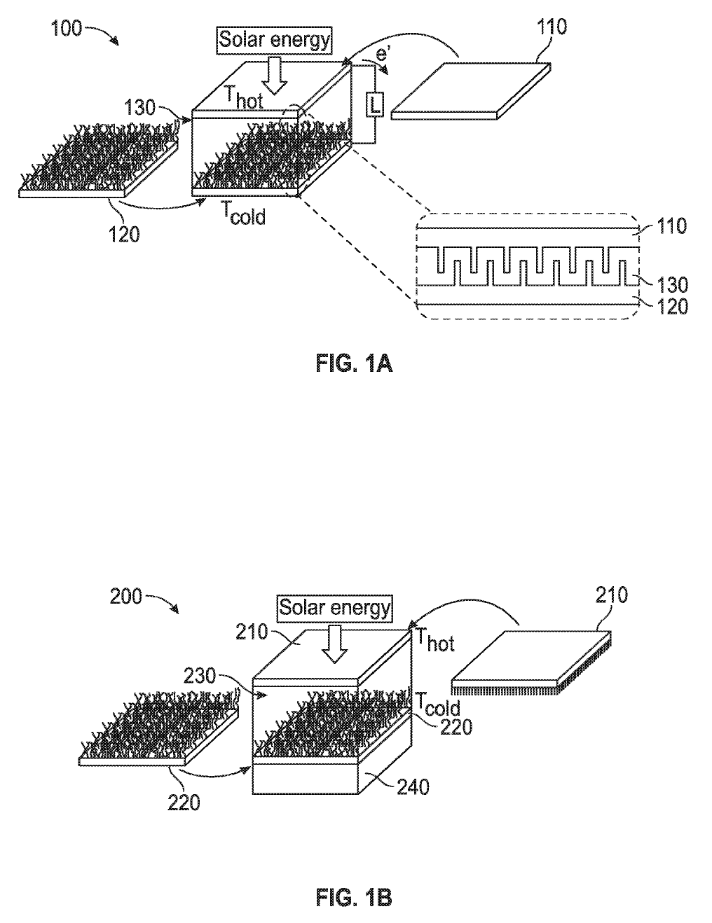

FIG. 1A illustrates a schematic representation of PV-TE power generation cell 100 having transport electrode 110, cathode 120, and PV material 130. Electrons are produced in PV material 130 and transported to cathode 120 through external load L. PV material 130, preferably an organometallic material, for example, a self-assembled ionic porphyrin binary solid or a self-assembled cooperative binary ionic (CBI) solid, are efficient in converting the UV-visible spectrum into electrons at the exited state due to their conjugated chains and ring structures. These excited electrons in PV material 130 are injected into a conduction band of transport electrode 110, such as, for example, ZnO nanowires on a transport contact (e.g., electron collector).

Referring to FIG. 1A, transport electrode or anode 110 is a hot electrode or anode and may include n-type materials with a crystalline structure (low density of defects). In one example, transport electrode 110 has ZnO nanowires that are fabricated using a solution-based process. Transport electrode 110 can be fabricated using evaporation, deposition or grown using both vacuum systems or in-air chemical solutions. The growth of the nanowires is typically carried out at between about 75-95° C. The processing costs associated with material synthesis are estimated to be between 15% and 20% less than the most common high temperature (>500° C.) grown nanowires. Moreover, the solution-based process of manufacturing ZnO nanowires allows scaling up the fabrication process. The electron losses due to crystal defects are estimated based on preliminary data to be less than about 1%.

PV material 130 is an organometallic material, preferably a self-assembled cooperative binary ionic (CBI) type material which is substantially transparent to near and mid IR radiation. The porphyrin CBI materials, which typically form various nano- and microscale structures, can be used as is, but in this form may not be compatible to integrate with the semiconductor and TE. Consequently, one embodiment includes a layer-by-layer deposition method for the porphyrin CBI materials that is performed at room temperature. The CBI materials are layered with controlled thicknesses and roughness on transport electrode 110 (e.g., ZnO nanostructures) and on cathode 120, thermoelectric nanostructures (e.g., Bi2Te3). The efficiency of PV material 130 is potentially better than the current best liquid electrolyte porphyrin dye-sensitized solar cell (12%) because of the possibility of using multilayer dye coating and better than the first all-solid-state DSSC (10%) since the CBI material also functions as an analog of the solid electrolyte coupling the TE and PV elements.

Cathode 120 can be, for example, p-type Bi2Te3, p-type Bi0.5Sb1.5Te3, or p-type Bi2Se3 nanostructured materials produced by either electrochemical deposition into the pores of anodic aluminum oxide membranes (nanowires), plasma sintering approach of nanopowders (nanocrystalline solid), or thermal evaporation. Cathode 120 is preferably Bismuth rich in order to show p-type behavior. A thermoelectric figure of merit for p-type Bi2Te3 can be about 1 at room temperature.

Cathode 120 captures the thermal energy of the infrared (IR) region producing hole-carrier diffusion and accumulation at the cold side of the device cell. At the same time, holes are transported across the PV material/cathode 120 interface. Charge separation is observed between PV material 130 and cathode 120 which is essential for establishing the contribution to power generation by both photovoltaic and thermoelectric elements.

In a typical porphyrin synthetized solar cell (Grätzel's cell), a 12% efficiency is reached. Similar to Gratzel's cells, PV-TE power generation cell 100 employs the UV-visible solar spectrum, but unlike Gratzel's cells, cell 100 also converts at least some of the IR energy into electricity by incorporating a thermoelectric component. In one example, assuming that PV-TE power generation cell 100 operates at Tₕₒₜ of approximately 350° C. and T_{cold} of about 25° C., the conversion of IR heat into electricity can provide an efficiency up to 40% (better than most state of the art PV devices).

FIG. 1B illustrates a schematic representation of PV-TE power generation cell 200 having transport electrode or anode 210, cathode 220, and PV material 230. Disposed on cathode 220 of PV-TE power generation cell 200 is energy storage component 240. The UV-visible and IR solar spectrums are converted into electric power by transport electrode 210, cathode 220 and PV material 230 and are stored in energy storage component 240. In one example, energy storage component 240 is a battery and more preferably a monolithically integrated lithium ion battery.

PV-TE power generation cell 200 includes energy storage component 240 which directs converted sunlight (UV, visible, and IR) as electricity. Energy storage component 240 can be monolithically integrated with PV-TE power generation cell 200. Energy storage component 240 can use anodes having the same material or other compatible materials such a silicone. Anode 210 and cathode 220 can be in the form of bulk, nanostructure or thin films. Lithium-Ion battery chemistry with silicon nanowire (SiNW) structures may be used as the anode. SiNW structures have a high lithium storage of about 4200 mAh/g in part due to the efficient one-dimensional charge transfer and delivery to the external load with lower losses. By placing energy storage component 240 on a cold side of PV-TE power generation cell 200, the energy storage operating temperature is low, so the energy storage does not suffer degradation of the performance due to high temperatures. PV-TE power generation cell 200 preferably includes an ultra-wide solar spectrum solid state dye sensitized solar cell and has highly efficient solar to electric power generation, highly efficient holes collection, highly electrical conductive organic photosensitive material, and simple processing.

Energy storage component 240 is preferably a battery system with lithium ion batteries having high efficient nanostructure silicon anodes. Silicon nanowires can be generated by patterning and etching silicon. Anisotropic etching of silicon (Si) with potassium hydroxide (KOH) can produce high aspect ratio square cross-section wires using (100) silicon, and rhombus or hexagonal cross-section wires using (110) silicon wafers. Either or both of these geometrical configurations have performance advantages in terms of specific power and energy density, and lifetime in terms of number of cycle.

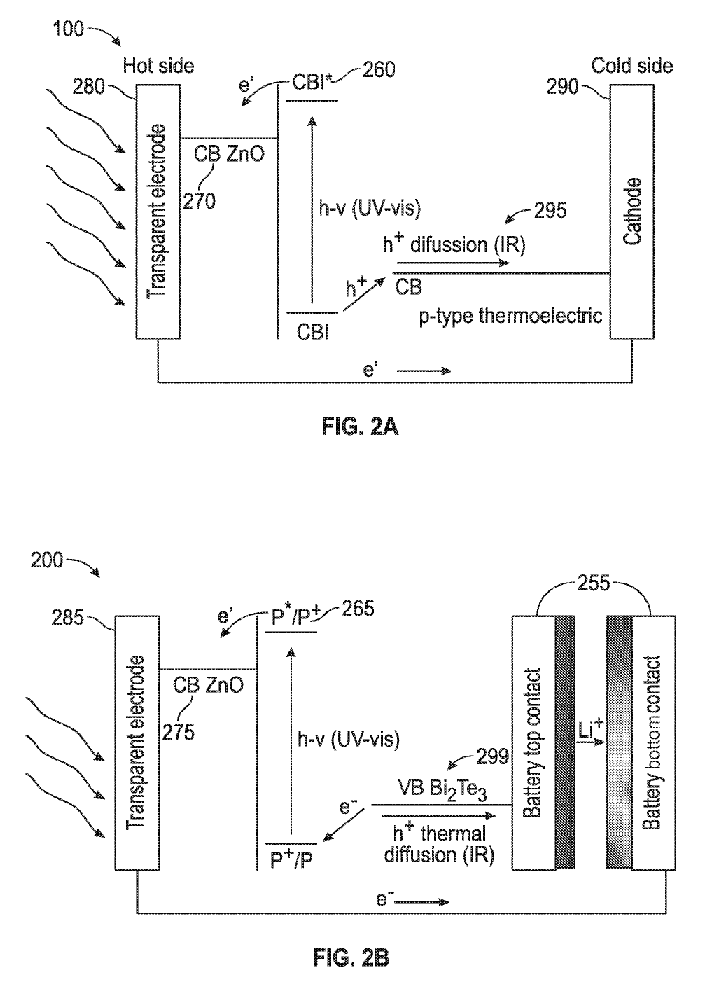

FIGS. 2A and 2B show two versions of electron and hole transport across the different materials of the PV-TE solar cell of FIGS. 1A and 1B. The injection of carriers to the corresponding bands is also included in FIGS. 2A and 2B; “CB” is the conductance band and “VB” is the valence band. Energy storage component 255 in FIG. 2B illustrates the energy density at the anode and cathode simulated with a software, for example, COMSOL. FIG. 2A illustrates an electron and hole transport across PV-TE power generation cell 100. FIG. 2B illustrates an electron and hold transport across PV-TE power generation cell 200. The excited electrons in PV materials 260 (e.g., CBI) are injected into conduction band 270 of ZnO nanowires 280. TE component 290 (e.g., p-type nanostructured material) captures the thermal energy of the infrared (IR) region producing carrier diffusion and accumulation on the cold side of the PV-TE power generation cell 100. At the same time, holes are transported across the CBI/TE interface 295. Charge separation between the CBI and TE component 290 establishes a contribution to power generation by both photovoltaic and thermoelectric element.

In FIG. 2B, the excited electrons in PV materials 265 (e.g., porphyrin) are injected into conduction band 275 of ZnO nanowires 285. Energy storage component 255 (e.g., lithium battery) captures the thermal energy of the infrared (IR) region producing carrier diffusion and accumulation on the cold side of the PV-TE power generation cell 200. At the same time, holes are transported across the P/TE interface 299. Energy storage component 255 captures the thermal energy of the IR region producing carrier diffusion and accumulation on the cold side of the PV-TE power generation cell 200. At the same time, holes are transported across the P/TE interface 295.

### Hole Conductor: P-Type Thermoelectric Nanostructured Material

A hole conductor for a typical dye sensitized solar cell (DSSC) is a I3-/I2 solution because its oxidation potential lies above the energy level of the highest occupied molecular orbital (HOMO) of the dye. The fluid solution allows for a good percolation of the hole conductor within the TiO₂-solar dye matrix. However, this solution is a limitation of DSSC because it is highly corrosive. Recent approaches for substituting the I3-/I2 solution have been focused on developing hole solid-conductors that can uniformly coat the nanoporous/mesoporous TiO₂ and have an energy level that allows hole transfer from the HOMO to the valence band of the conductors. This approach is known as “solid-state DSSC”. Organic electrical conductors have oxidation potentials above the energy level of the HOMO of the dye and are not highly corrosive. For example, Spiro-OMeTAS (2,2′,7,7′-tetrakis(N,N-di-pmethoxypheny-amine)-9,9′-spirobi-fluorene) and P3HT (poly(3-hexylthiophene)) are a few materials that have been investigated. The efficiency of solid-state DSSC has been reported to be substantially smaller than liquid-based hole transporter cells. The low efficiency is the result of the low hole mobility of organic conductor materials. Small mobilities increase the number of electron-hole recombination events between the electron located in the electron-collector material and the hole conductor before holes can reach the cathode.

Due to the photosensitive nature of an organic dye, DSSC generally operates (i.e. is photoactive) within the ultraviolet to visible region. There has been limited progress for collection in the infrared (IR) spectrum. Collecting more of the infrared (IR) radiation can increase the overall efficiency of the system making DSSC more competitive. Thermoelectric materials are capable of converting heat into electric power and they have been used for space and heat-waste recovery applications. Solar thermoelectric generators (STGs) were developed to convert IR solar spectrum into electric power by the use of thermoelectric devices placed between the hot surface (surface collecting IR) and the heat-sink surface (on the opposite side of the device). The overall efficiencies for STGs are reported between 4 to 12% for bulk inorganic thermoelectric materials which are substantial when they are compared with commercial silicon PVs. Furthermore, nanostructured materials are known to have a larger thermoelectric efficiency compared to their bulk counterparts. Integrating a thermoelectric element to a DSSC may increase the overall efficiency.

In one non-limiting example, the overall efficiency of the PV-TE power generation cell 100 can be estimated by the sum of the photovoltaic and thermoelectric efficiencies:

$${η}_{PV - TE} = {η}_{PV} + \frac{{T}_{hot} - {T}_{cold}}{{T}_{hot}} \frac{\sqrt{1 + Z \overline{T}} - 1}{\sqrt{1 + Z \overline{T}} + {T}_{cold} / {T}_{hot}}$$

where η_{PV-TE} is the overall efficiency, η_{PV} is the efficiency of the photovoltaic element, (Tₕₒₜ−T_{cold})/Tₕₒₜ is the Carnot efficiency, and ZT is the average dimensionless thermoelectric figure of merit for the material at the average temperature T (T=0.5 [Tₕₒₜ−T_{cold}]). The last term on the right hand side accounts for the thermoelectric efficiency. Assuming that Tₕₒₜ=50° C. (temperature on the hot side of the thermoelectric element), T_{cold}=25° C., and ZT=0.5 (a conservative ZT value for a good thermoelectric material), an efficiency of about 1% can be added to the PV element. This thermoelectric efficiency is comparable to the efficiency of some solid-state DSSC. With 100-sun concentration, Tₕₒₜ=350° C. can be obtained which can yield a thermoelectric efficiency as high as 7% when T_{cold}=25° C. Assuming η_{PV}=10% for state of the art solid-state DSSC, a calculated η_{PV-TE} of 17% with solar concentration (almost double of the PV efficiency alone) can be achieved with the proposed PV-TE device. Please note that Tₕₒₜ=350° C. was selected in this example because the porphyrins do not degrade at such temperature.

### Transparent Conductive (TC) Nano Wires and TC Oxide: ZnO as Electron Collector (Top Electrode)

Zinc oxide (ZnO) is a wide bandgap (3.3-3.4 eV) II-VI compound intrinsically n-type semiconductor and piezoelectric material. It has a stable wurtzite structure with lattice spacing of a=0.325 nm and c=0.521 nm. ZnO has attracted intensive research effort due to its unique properties and versatile applications in transparent electronics, ultraviolet (UV) light emitters, piezoelectric devices, chemical sensors, and spin electronics. Because of the physical properties and the motivation of device miniaturization, large effort has been focused on the synthesis, characterization and device applications of ZnO nanomaterials.

The properties of ZnO as a transparent conductive oxide (TCO) have been investigated for both bulk and thin films. In the field of DSSC, ZnO nanowire (NW) photoelectrodes have been exploited in order to improve the electron transfer by virtue of eliminating the grain boundaries. Typically the DSSC uses a fluorine tin oxide (FTO) as a TCO to transfer the excited electrons from the nanostructured semiconductor. The combination of TiO₂ nanoparticles and the FTO has been combined for the DSSC. A single crystalline ZnO NW has a similar energy band position as TiO₂, which makes it suitable for highly efficient photoelectrode materials. However, the energy conversion efficiency of the ZnO NW-based DSSCs is inferior to the TiO₂ nanoparticle-based DSSCs. Moreover, the small difference in the work function between ZnO (5.1-5.3 eV) and FTO (4.9 eV) does not provide sufficient driving force for the charge injection from the ZnO NWs to FTO, which implies that new TCO materials may be exploited in ZnO NW-based DSSCs.

In one example, ZnO NW were grown on both ALO and FTO films. The morphologies of the ZnO NW arrays grown on both Aluminum Zinc Oxide (AZO) as a TCO and FTO films were similar. However, the AZO-based DSSC exhibited better energy conversion efficiency than the FTO-based one. The fill factor (FF) of the AZO-based photoelectrode was about 42.4%, which was larger than the FTO-based one (about 37.8%). Remarkably, the short circuit current density, Jsc, of the AZO-based photoelectrode significantly increased from about 2.0 to about 2.5 mA/cm², corresponding to a 25% improvement. The increased FF and Jsc can be explained by the ohmic contact behavior of the ZnO NWs array grown on the AZO film in contrast to the Schottky contact of the FTO based ZnO NWs array. The work function of the AZO was found to be less than about 4.6 eV. Therefore, the ohmic contact with the AZO film was formed because the work function of ZnO was larger than AZO. Also, the similar chemical compositions of ZnO and AZO were favorable for the formation of a strong chemical bond at the ZnO/AZO interface, which facilitated the charge transfer from the ZnO NW to the AZO film.

### Organic Photosensitive Material: Porphyrins and Cooperative Binary Ionics

A nanoscale porphyrin-based semiconductor material that can perform efficient light-harvesting, charge separation and transport, and exciton transport can be integrated into photovoltaic/thermoelectric solar cells. This nanoscale porphyrin-based semiconductor material is a new class of self-assembled materials, called cooperative binary ionic (CBI) solids. The CBI materials represent a new type of binary solid based on the ionic self-assembly of oppositely charged porphyrins and phthalocyanines. CBI materials offer opto-electronic properties that can be used to improve an efficiency of a solar cell by controlling nanoscale integration, light-harvesting, energy transport, and charge-separation. Platinum nanocomposites with CBI nanostructures have demonstrated the advantages of these CBI nanomaterials in efficient and durable visible light-driven hydrogen production. However, the enormous variety of binary porphyrin combinations, nanostructure morphologies, and functional properties that are achievable with the CBI materials provide a myriad of other opportunities for greatly improving other solar technologies including photovoltaics.

CBI solids are self-assembled binary porphyrin nanomaterials that offer a fresh approach for integrating the elements of hybrid solar cells. First, the CBI nanomaterials naturally possess strong visible light absorptivity because they are composed of ionic porphyrins, expanded porphyrins, or phthalocyanines. Second, the energy levels, light absorption and emission, lifetimes, and redox properties of the CBI materials can be modified by synthetically altering the porphyrin subunits in various ways. Finally, it is possible to control the size (nano- and microscale), shape, crystalline structure, degree of crystallinity, and surface area of the CBI materials using nano-engineered methods.

### Thermoelectric Nanowires

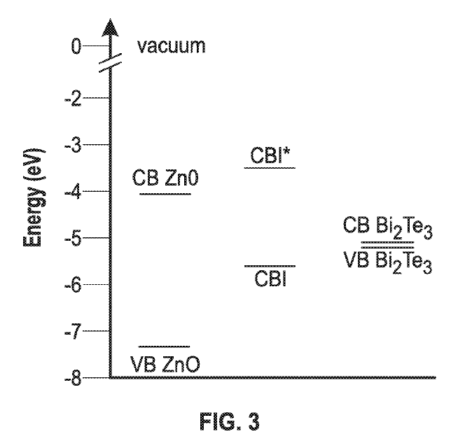

One of the factors for the selection of the thermoelectric hole-transporter material (TE-HTM) is the formation of a uniform and conformal layer of porphyrin onto the thermoelectric element, so hole transport across the interface is not limited by imperfections of the adsorbed layer. Bi2Te3 nanowires have high electrical conductivity, high carrier mobility, and large ZT at about 300 K. Furthermore, Bi2Te3 can be prepared in solution, and be incorporated into organic conductor supports. Bi2Te3 is a narrow band gap material (0.24 eV) with a working function of about 5.3 eV. FIG. 3 shows the relative energy of the conduction and valence bands for ZnO, CBI, and Bi2Te3. As seen in FIG. 3, the injection of holes from the HOMO level of the CBI into the valence band of the Bi2Te3 is energetically favorable. Since tellurium is not an earth-abundant element, Bi2Te3 may be replaced by other compounds, for example, thermoelectric nanostructured materials such as doped-Bi2Se3 and Cu2GeSe3 can also be used.

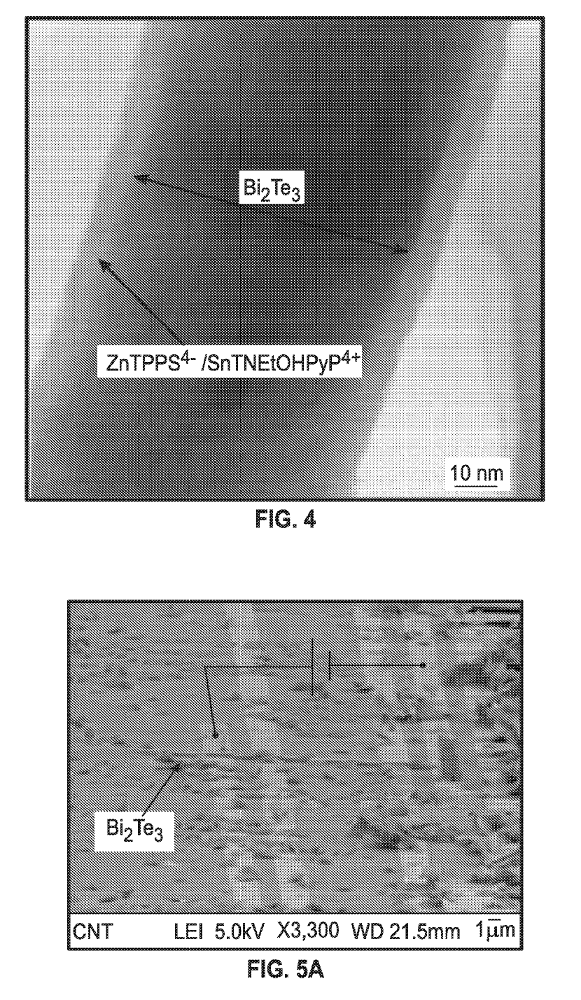

In one example, Bi2Te3 nanowires (gold catalyzed) and nanoplatelets (catalyst free) were synthesized by standard thermal chemical vapor deposition methods. Deposition of water-soluble CBI porphyrins ZnTPPS at about pH 6.6 and ZnTNEtOHPyP at about pH 7.1 was carried out onto the Bi2Te3 Nanowires. Transmission electron microscopy (TEM) studies of the ZnTPPS⁴⁻/SnTNEtOHPyP⁴⁺ 12 layer coated Bi2Te3 (first layer ZnTPPS⁴⁻) showed a uniform multilayer of about 6 nm thick, see, for example, the image of the multilayer in FIG. 4. The patterns on the Bi2Te3 in FIG. 4 are an indication of the high crystal quality of the sample. There was no substantial difference in layer uniformity and thickness between the ZnTPPS⁴⁻ and SnTNEtOHPyP⁴⁺ (data not shown) adsorbed as first layer onto Bi2Te3, which may indicate that the overall electric charge of the porphyrin was not influencing the adsorption process for those solutions, so short range non-electrostatic adsorption may have been driving the adsorption force. The different degrees of hydrophobicity between ZnTPPS⁴⁻ and SnTNEtOHPyP⁴⁺ (been the SnTNEtOHPyP⁴⁺ more hydrophobic) were not relevant for the adsorption process. However, ZnTPPS⁴⁻ and SnTNEtOHPyP⁴⁺ yielded different adsorption characteristics onto carbon nanotubes, which was a difference with respect to Bi2Te3. A possible explanation was the presence of the thin native oxide layer (approximately 1 nm) on the surface of the Bi2Te3 nanowire. This oxide was reported to be Bi—O—Te, and it can present a low surface density of —O—O— groups and dangling bond defects. These un-pair electrons can render the surface amphiphilic helping to produce a uniform initial layer of SnTNEtOHPyP⁴⁺ which complements with the other adsorption mechanisms.

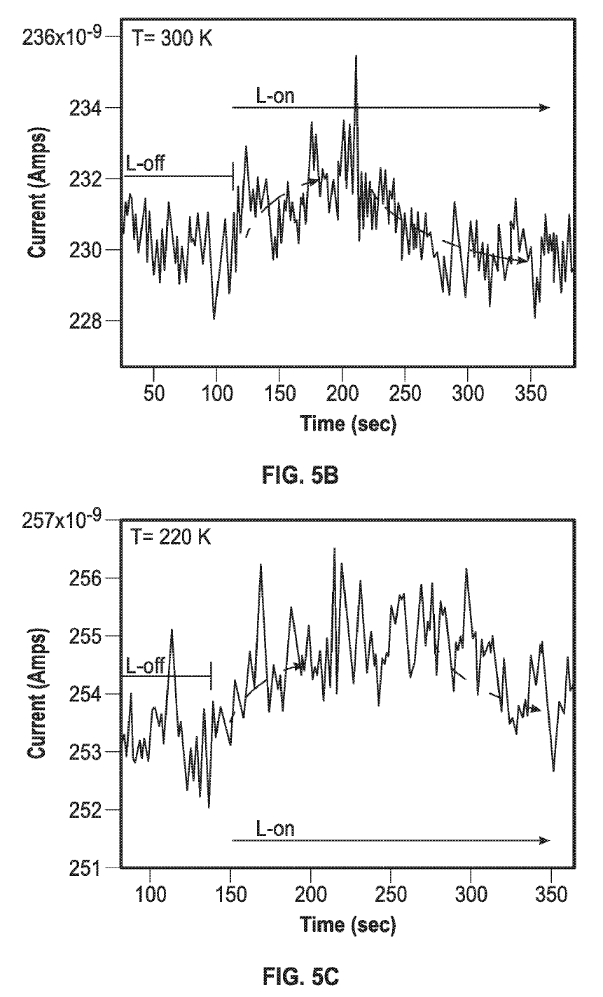

In this example, various factors influenced the overall thermoelectric behavior due to the presence of photo-activated carriers (photoactivated porphyrin) for TE-HTM materials and photoactivated carrier injection from the CBI into the p-type Bi2Te3 nanowires. FIG. 5A shows a thermoelectric characterization platform employed for chemical vapor deposition (CVD) grown p-type Bi2Te3 nanowires. FIGS. 5B and 5C show electrical conductivity (photoconductivity) as a function of incident light exposure at two different temperatures. L-on indicates light on, and L-off indicates light off. In this example, the light was white light with an intensity of about 1000 W/m². The incident light was 1-sun solar power density of white light. Right after illumination, the electrical resistance decreased due the photo-excitation of SnTNEtOHPyP⁴⁺/ZnTPPS⁴⁻ layer. This observation was also supported by the fact that the electrical resistance was almost a linear function of temperature, so the heat from the lamp source could not be responsible for the observed current gain. Negative charges were photo-g generated in both SnTNEtOHPyP⁴⁺ and ZnTPPS⁴⁻, but SnTNEtOHPyP⁴⁺ was electron acceptor with respect to ZnTPPS⁴⁻. Electrons in SnTNEtOHPyP⁴⁺ can be injected into the p-type Bi2Te3 as well. However, holes cannot be energetically injected from the p-type Bi2Te3 into HOMO level of SnTNEtOHPyP⁴⁺. This may result in an overall positive layer on the surface of the NW, which may yield a decrease of the electrical conductivity after the charge is completely transferred. After about 100 seconds of light exposure, the resistance started to increase, which may have been associated with the lamp source heating the sample or the positive polarization of the porphyrin layer.

### Transparent Conductive Oxide Nano Wires: ZnO

The optical properties of a solar cell determine how much light enters the cell and thus, the quantity of light capable of generating an electron-hole pair. The movement of the sun and broadband solar spectrum provide a range of incident angles and wavelengths. Thus, improving optical properties optimizes the structure of the solar cell to admit light at a larger range of angles and energies. Two conventional ways to improve the optical properties of solar cells are light trapping and anti-reflection coatings. These methods increase the amount of light that enters the cell, but are limited in their ability to exploit the broadband spectrum or account for the movement of the sun. Using nanowires to create a gradient index anti-reflection coating preferably optimizes the amount of solar radiation capable of entering a cell.

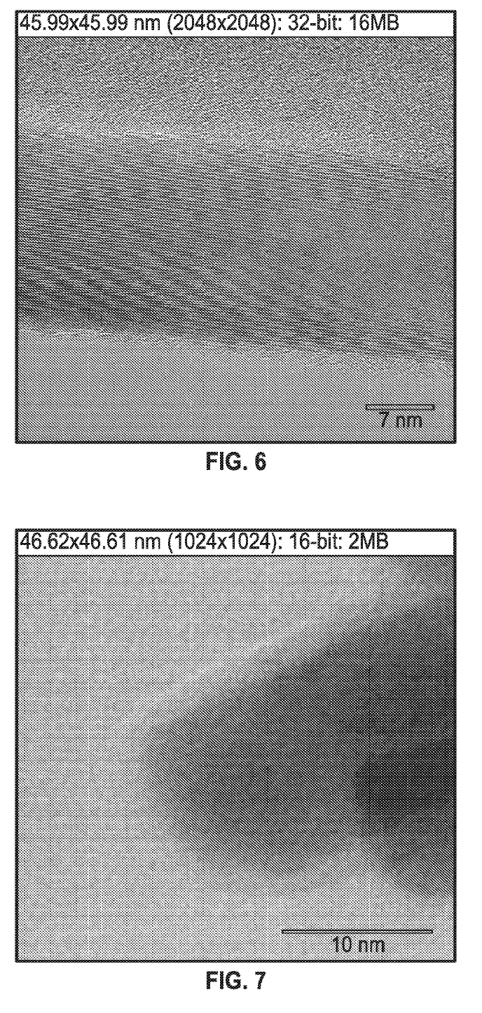

ZnO nanowires can be grown by aqueous chemical growth on glass coated either with gold or a ZnO:Al (AZO) seeding layer, to create a continuous layer of nanowires (NW). In a non-limiting example, the effect of layering of the organic photoexcited materials, such as CBI and the porphyrin materials, was studied. The nanowire arrays were characterized using TEM images and x-ray diffraction (XRD). FIG. 6 shows an example of a TEM image of a nanowire, with a number of fringes present. In this example, ZnO nanowires grown by aqueous chemical growth on glass had average diameters between about 40 nm and about 100 nm, and average lengths between about 200 nm and about 800 nm. The ZnO nanowires had vertical alignment and presented a dense structure. The ZnO nanowires also exhibited relatively small diffuse reflectivity and a good transparency in the UV-VIS range.

FIG. 7 shows an image of an organic layer having a thickness of about 3 nm. In this example, the ZnO NWs were deep coated alternatively with about five bilayers of ZnTNEtOHPyP and ZnTPPS. In this example, the anionic (ZnTPPS) layer was washed with water after each application, and the cationic layer was not. The calculated thickness for each bilayer was about 0.5-0.6 nm, which matched the example data observed in FIG. 6. The quality of the coating was high, and there was a substantially uniform interface between the ZnO and the organic material. The layers also appeared to be substantially defect free, specifically, the layer composed of both ZnTPPS and ZnTNEtOHPyP, which was an ethanol type group. ZnO has demonstrated chemisorption towards ethanol and alcohol. Oxygen vacancies on metal-oxide surfaces are electrically and chemically active. These vacancies function as n-type donors and can significantly increase the conductivity of the oxide. Upon adsorption of charge accepting molecules at the vacancy sites, such as NO₂ and O₂, electrons are effectively depleted from the conduction band, leading to a reduced conductivity of the n-type oxide. On the other hand, molecules such as CO and H₂ react with surface adsorbed oxygen and consequently remove it, leading to an increase of conductivity. Moreover, the non-centro symmetric ZnO crystal structure of this example resulted in a spontaneous polarization and polar faces dominated nanostructures. The crystal structure of ZnO can be visualized in a way where oxygen atoms and zinc atoms are tetrahedrally bonded. These tetrahedrons stack along the [0001] direction. Due to spontaneous polarization, the position of positive charge is displaced from that of negative charge and the direction of displacement is also along the [0001] direction. The net result of this polarization is a charged [0001] ZnO surface. Those properties result in a catalytic effect for the porphyrins, which tend to naturally deposit onto the NWs. The porphyrin film may neutralize defects (i.e. decrease defect density) at the interface of the film and the ZnO surface.

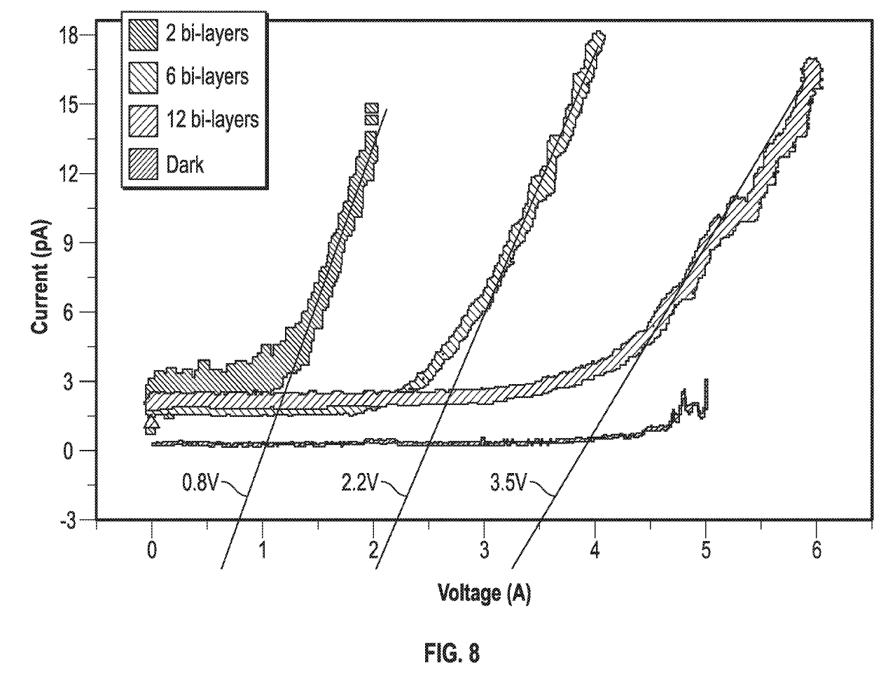

FIG. 8 is a graph illustrating electrical characterization of ZnO-porphyrin coated nanowires under dark and light-on conditions. Photo-excitation of the porphyrin is preferable in order to achieve electrical conduction. The different currents versus voltage curves are related to an increasing of the organic layers onto the ZnO. The threshold voltage increases as the number of organic layers increases demonstrating that the organic layer is well assembled, i.e. does not leak current, and that it behaves as a diode-like structure.

### The Organic Photosensitive Material: Porphyrins and Cooperative Binary Ionics (CBI)

Production of controlled films of the porphyrins and CBI materials on inorganic semiconductors such as Bi2Te3 and ZnO can be manufactured by layer-by-layer deposition of the porphyrins and CBI materials on carbon nanotubes, glass, silicon, Bi2Te3, and ZnO. Deposition of water-soluble porphyrins, such as ZnTPPS and ZnTNEtOHPyP onto various surfaces can also be used. TEM studies of these porphyrins bound to carbon nanotubes (CNTs) revealed that the morphology of the layers of porphyrin on carbon nanotubes differed between the two ionic porphyrins, with ZnTPPS⁴⁻ giving substantially smooth relatively uniform approximately 2-nm thick layers on 1.1 nm single-walled CNTs, while ZnTNEtOHPyP⁴⁺ gave mostly thicker layers of porphyrin with non-uniform thickness. The difference in adsorption behavior was due to differences in hydrophobicity of the two porphyrins. There was an interaction of porphyrins with inorganic semiconductor and thermoelectric nanostructures (especially nanowires), and not CNTs or grapheme.

Layer-by-layer adsorption of ionic porphyrins and CBI materials onto glass, silicon, and gold surfaces was met with mixed results. Layers of single porphyrins on glass for instance was found to be highly conductive in some cases but not for other porphyrins layers prepared in the same manner. In addition, optical and atomic force microscopy (AFM) imaging suggested that the layers formed by the layer-by-layer adsorption method did not provide substantially uniform coverage at the microscale. Only a small parameter space and range of ionic porphyrins was examined at this stage and more consistent and uniform films may be attained.

Similarly, layer-by-layer deposition of binary combinations of ionic porphyrins suffered from the same non-uniformity when deposited onto large flat areas on glass and gold. Deposition of ionic porphyrins showed behavior similar to polyelectrolytes of opposite charge when deposited on surfaces by layer-by-layer deposition methods. Specifically, after the initial layer of one of the porphyrins was deposited, the addition of a layer of opposite charged porphyrin was observed (by optical spectrophotometry) to partially remove some of the previously applied layer. Subsequently, as more layers were added, each new layer partially removed some of the previous oppositely charged porphyrin monolayer. This behavior was to be expected as the charge neutrality was maintained as the growing binary ionic material was built up on the surface.

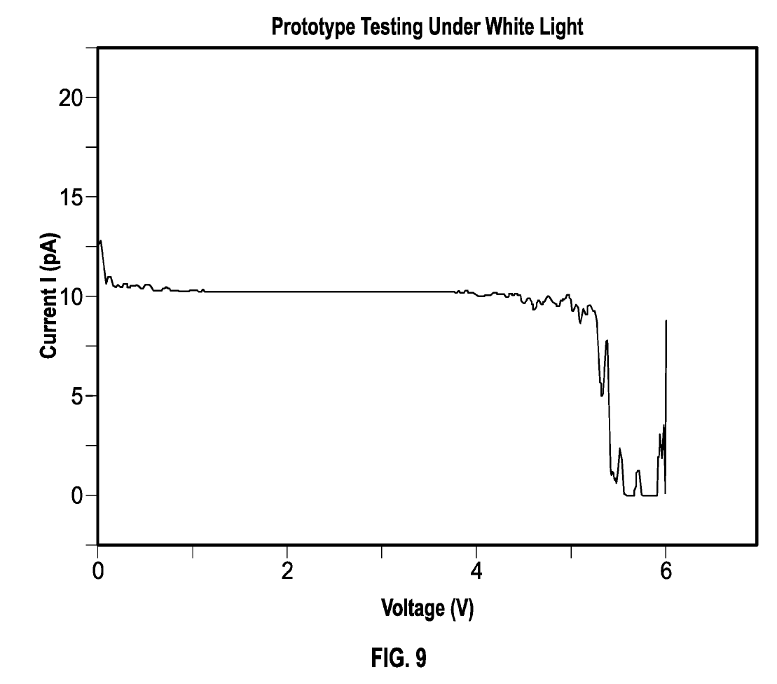

FIG. 9 is a graph illustrating voltage versus current of an example PV-TE solar cell. The example solar cell was tested under a UV-visual incandescent light. The example was also tested under a power irradiance and was measured to be about 0.5 sun (500 w/m2). FIG. 9 shows the example PV-TE solar cell with output in terms of current-voltage plot. The Open Circuit Voltage (VOC) was measured to be about 4.5V. The voltage of the example PV-TE solar cell depended on the number of organometallic (e.g., CBI) layers. For this example, the number of organometallic layers was about 12 to 15. The current density was calculated to be about 18 mA/cm² with a power density of about 90 mW/cm².

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology, its practical application, and to enable others skilled in the art to utilize the technology in various embodiments and with various modifications as are suited to the particular use contemplated. It is intended that the scope of the technology be defined by the claim.

1. A photovoltaic-thermoelectric solar cell comprising:
a substantially transparent electrode;
an organometallic photovoltaic material disposed on the transparent electrode; and
a cathode disposed on the organometallic photovoltaic material.

2. The photovoltaic-thermoelectric solar cell of claim 1 wherein the transparent electrode comprises an n-type material with a crystalline structure.

3. The photovoltaic-thermoelectric solar cell of claim 2 where the n-type material with a crystalline structure comprises zinc oxide.

4. The photovoltaic-thermoelectric solar cell of claim 3 wherein the zinc oxide transparent electrode comprises a zinc oxide nanowire photoelectrode.

5. The photovoltaic-thermoelectric solar cell of claim 1 wherein the organometallic photovoltaic material comprises a porphyrin nanomaterial.

6. The photovoltaic-thermoelectric solar cell of claim 5 wherein the porphyrin nanomaterial comprises a self-assembled cooperative binary ionic nanomaterial.

7. The photovoltaic-thermoelectric solar cell of claim 1 wherein the cathode comprises a p-type thermoelectric nanostructured material.

8. The photovoltaic-thermoelectric solar cell of claim 7 wherein the p-type thermoelectric nanostructured material comprises a p-type Bi2Te3 nanostructured material.

9. The photovoltaic-thermoelectric solar cell of claim 1 further comprising an energy storage component disposed on the cathode.

10. The photovoltaic-thermoelectric solar cell of claim 9 wherein the energy storage component comprises an ion battery.

11. The photovoltaic-thermoelectric solar cell of claim 9 wherein the energy storage component comprises a monolithically integrated ion battery.

12. The photovoltaic-thermoelectric solar cell of claim 9 wherein the energy storage component is integrated with the cathode.

13. A method of manufacturing a photovoltaic-thermoelectric solar cell comprising:
applying one or more first layers of organometallic photovoltaic material to an electrode;
applying one or more second layers of organometallic photovoltaic material to a cathode; and
disposing the one or more first layers of the applied organometallic photovoltaic material adjacent to the one or more second layers of applied organometallic photovoltaic material to form the photovoltaic-thermoelectric solar cell, wherein the photovoltaic-thermoelectric solar cell has layers of organometallic photovoltaic material disposed between the electrode and the cathode.

14. The method of claim 13 wherein the method is performed at room temperature.

15. The method of claim 13 wherein the organometallic photovoltaic material comprises a porphyrin nanomaterial.

16. The method of claim 13 wherein the electrode comprises an n-type material with a crystalline structure.

17. The method of claim 13 further comprising applying one or more additional layers of organometallic photovoltaic material between the electrode and the cathode in order to increase an open circuit voltage of the solar cell.

18. The method of claim 13 wherein the cathode comprises a p-type thermoelectric nanostructured material.

19. The method of claim 13 further comprising disposing an energy storage component on the cathode.

20. The method of claim 18 wherein the energy storage component comprises a battery.
